(19) United States
(12) Patent Application Publication
(10) Pub. No.: US 2025/0192037 A1
(43) Pub. Date: Jun. 12, 2025

(54) BURIED METAL JUMPER STRUCTURE FOR BEOL

(71) Applicant: INTERNATIONAL BUSINESS MACHINES CORPORATION, ARMONK, NY (US)

(72) Inventors: Ruilong Xie, Niskayuna, NY (US); Nicholas Anthony Lanzillo, Wynantskill, NY (US); Brent A. Anderson, Jericho, VT (US); Lawrence A. Clevenger, Saratoga Springs, NY (US); Albert M. Chu, Nashua, NH (US); Reinaldo Vega, Mahopac, NY (US)

(21) Appl. No.: 18/530,641

(22) Filed: Dec. 6, 2023

(51) Int. Cl. H01L 23/528; H01L 21/768; H01L 23/48; H01L 23/532

(52) U.S. Cl. CPC H01L 23/5283; H01L 21/768; H01L 23/481; H01L 23/53257

(57) ABSTRACT

A microelectronic structure including an underlying device. An interconnect located on the underlying device. Interconnect includes a first Mx metal line and a second Mx metal line. The first Mx metal line is located adjacent to the second Mx metal line. A jumper connects the first Mx metal line to the second Mx metal line and the first Mx metal line extends higher than the jumper.

### BACKGROUND

The present invention generally relates to the field of microelectronic, and more particularly to formation of a jumper for a Mx lines within an interconnect structure.

Nanosheet is the lead device architecture in continuing CMOS scaling. However, nanosheet technology has shown issues when scaling down such that as the devices become smaller and closer together, they are interfering with each other. Forming connections between different metal lines can limit the size/dimension of other lines because it can lead to electrical shorts from the lines overlapping or being too close to each other.

### BRIEF SUMMARY

Additional aspects and/or advantages will be set forth in part in the description which follows and, in part, will be apparent from the description, or may be learned by practice of the invention.

A microelectronic structure including an underlying device. An interconnect located on the underlying device. Interconnect includes a first Mx metal line and a second Mx metal line. The first Mx metal line is located adjacent to the second Mx metal line. A jumper connects the first Mx metal line to the second Mx metal line and the first Mx metal line extends higher than the jumper.

A microelectronic structure including an underlying device and an interconnect located on the underlying device. The interconnect includes a plurality of Mx metal lines where at least one Mx metal line of the plurality of Mx Metal lines includes an integral connecting via. At least one jumper connecting at least two adjacent Mx metal lines of the plurality of Mx metal lines. The at least one Mx metal line with the integral connecting via extends higher than the at least two adjacent Mx metal lines.

A microelectronic structure including an underlying device and an interconnect located on the underlying device. The interconnect includes a plurality of Mx metal lines. At least one or more jumpers connecting a group Mx metal lines of the plurality of Mx metal lines. The group of Mx metal lines includes three adjacent Mx metal lines. Each of the Mx metal lines in the group of Mx metal lines extends higher than the at least one or more jumpers.

A method including the steps of forming an underlying device and forming an interconnect located on the underlying device. Interconnect includes a first Mx metal line and a second Mx metal line. The first Mx metal line is located adjacent to the second Mx metal line. A jumper connects the first Mx metal line to the second Mx metal line and the first Mx metal line extends higher than the jumper.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of an interconnecting having a jumper, in accordance with the embodiment of the present invention.

FIG. 2 illustrates a cross section view of a metal layer, in accordance with the embodiment of the present invention.

FIG. 3 illustrates a cross section view of the interconnect after etching the metal layer to form the Mx level and the Via level, in accordance with the embodiment of the present invention.

FIG. 4 illustrates a cross section view of the interconnect after formation and patterning of a first lithography layer, in accordance with the embodiment of the present invention.

FIG. 5 illustrates a cross section view of the interconnect after etching the base layer and formation of the jumper, in accordance with the embodiment of the present invention.

FIG. 6 illustrates a cross section view of the interconnect after removal of the first lithography layer, formation of a second lithography layer, and patterning/etching of the plurality of metal lines, in accordance with the embodiment of the present invention.

FIG. 7 illustrates a cross section view of the interconnect after removal of the second lithography layer and the hardmask, formation of an interlayer dielectric layer, in accordance with the embodiment of the present invention.

FIG. 8 illustrates a cross section view of the interconnect after formation of a second interlayer dielectric layer and formation of Mx+1 metal lines, formation of an interlayer dielectric layer, in accordance with the embodiment of the present invention.

FIG. 9 illustrates a top-down view of an interconnecting having a double jumper, in accordance with the embodiment of the present invention.

FIG. 10 illustrates a cross section view of the interconnect utilizing a double jumper after formation of a second interlayer dielectric layer and formation of Mx+1 metal lines, formation of an interlayer dielectric layer, in accordance with the embodiment of the present invention.

FIG. 11 illustrates a top-down view of an interconnecting having two offset jumpers, in accordance with the embodiment of the present invention.

FIG. 12 illustrates a top-down view of an interconnecting having a plurality of jumpers, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of +8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards an interconnect structure, for example, a back-end-of-the-line (BEOL) structure or a backside-power-distribution-network (BSPDN). These structures are comprised of different metal lines (e.g., Mx, Mx+1 metal lines), and connecting vias with the components distributed on multiple levels. The connecting vias (or via level) can be integrally formed with the Mx metal lines. The design for the interconnect can require that some of the different metal lines, for example, on the Mx level need to be connected to each other. When a connection is formed on top of the Mx metal lines (i.e., on top of the via level), e.g., in the form of a metal bridge, then the bridge placement interferes with the placement of the Mx+1 metal lines. When the Mx+1 metal lines are located close to the bridge which can lead to the formation of an electrical short. Furthermore, the placement/location of the bridge affects the sizing of the Mx+1 metal lines.

In contrast to the formation of the metal bridge (i.e., bridges on top of the via level) the present invention forms jumpers between adjacent Mx metal lines. The jumper is located at the base of the Mx metal lines thus the jumper does not affect the placement/size or interfere with the Mx+1 metal lines located on top of the via level. The Mx metal lines (with an integral via level), Mx metal lines (without an integral via level), and an integral jumper are formed from the same metal layer. The different components are formed by selectively removing different portions of the metal layer, which allows for the reduction of miss alignment processing errors.

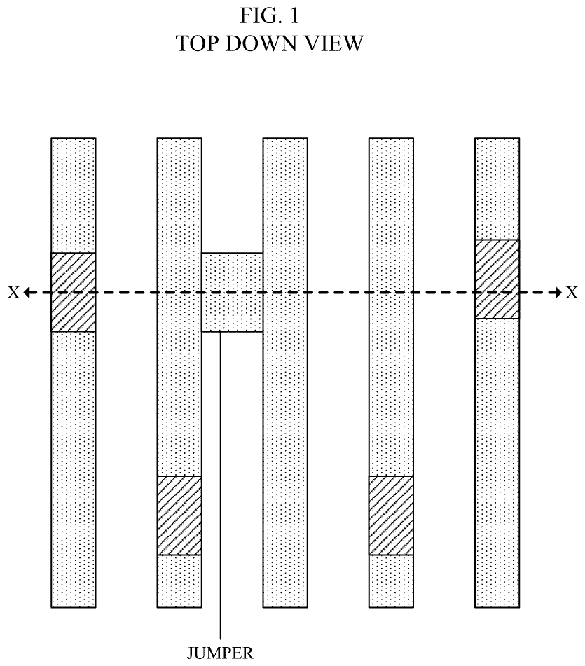

FIG. 1 illustrates a top-down view of an interconnect, in accordance with the embodiment of the present invention. The cross-section X extends horizontally through the interconnect across multiple metal lines, where the cross-section passes through the jumper.

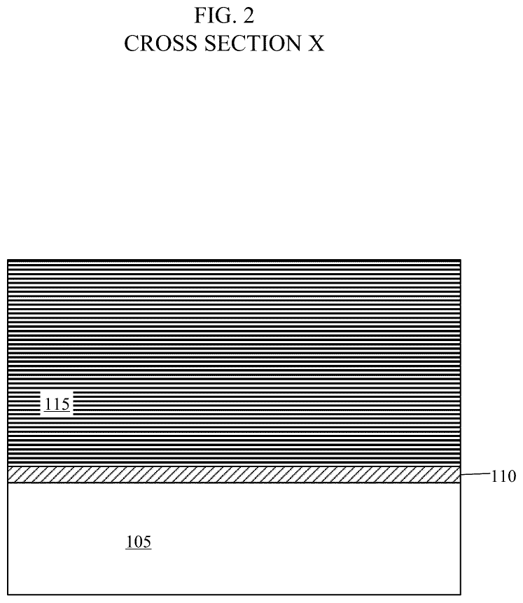

Referring now to FIG. 2, a structure is shown during an intermediate step of a method of fabricating a metal layer on top of an underlying device 105. The underlying device region 105 can be any type of electronic device that needs an interconnect, BEOL layer, or a BSPDN, for example, the underlying device region 105 can be a logic device, integrated circuit, a passive device, or some other type of electronic device. The interconnect (or multiple interconnects) can be located on the frontside and/or backside of the underlying device 105. A first layer 110 is formed on top of the underlying device 105, where the first layer 110 can be, for example, TiN or TaN or another suitable material. A metal layer 115 is formed on top of the first layer 110, the metal layer 115 is comprised of a conductive metal, for example, Ru, Cu or another suitable conductive metal.

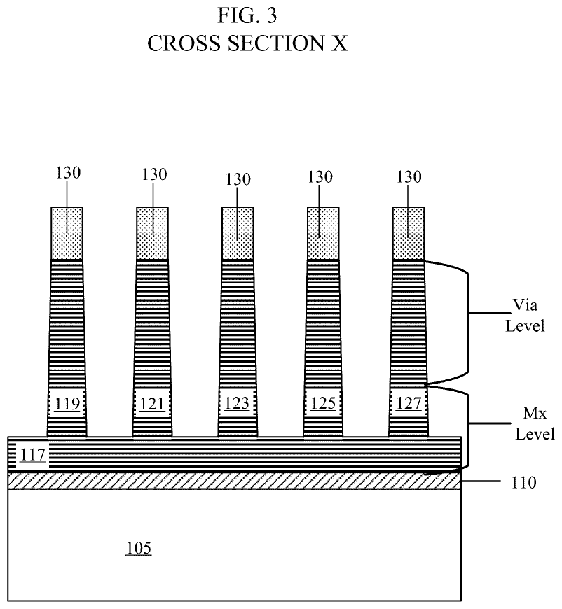

FIG. 3 illustrates the processing stage after etching the metal layer 115 to form the Mx level and the Via level. A hardmask 130 is formed on top of the metal layer 115. The hardmask 130 and the metal layer 115 are etched to form a plurality of metal lines 119, 121, 123, 125, and 127. The metal layer 115 is not completely etched to separate each of the plurality of metal lines 119, 121, 123, 125, and 127 (i.e., the metal layer 15 is not through to the first layer 110 or to the underlying device 105). A base layer 117 remains after the etching process to form the plurality of metal lines 119, 121, 123, 125, and 127. Each of the plurality of metal lines 119, 121, 123, 125, and 127 are connected to each other via the base layer 117, i.e., the base layer 117 is formed internally with each of the plurality of metal lines 119, 121, 123, 125, and 127. Each of the plurality of metal lines 119, 121, 123, 125, and 127 are comprised of an integral Mx level section and a Via level section, meaning that the connecting vias (i.e., the via level) is formed with the Mx metal lines (i.e., the Mx level). Thus, the single etching process forms the Mx level metal lines and the connecting vias (i.e., the Via level) out of a single metal layer 115.

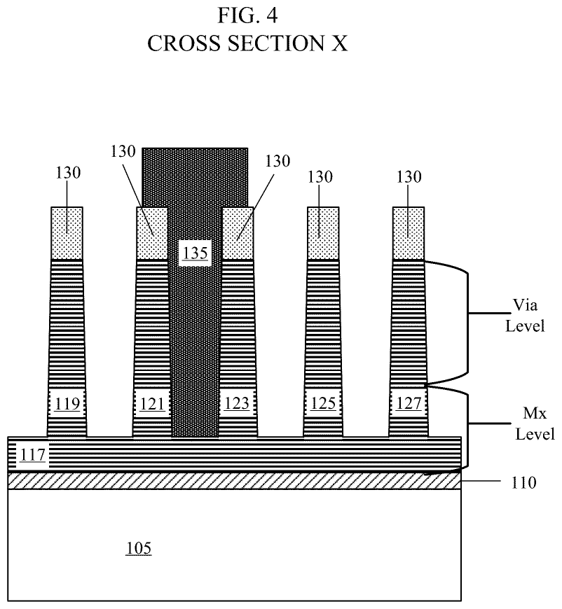

FIG. 4 illustrates the processing stage after formation and patterning of a first lithography layer 134. A first lithography layer 135 is formed on top of the hardmask 130, on top of the base layer 117, and around each of the plurality of metal lines 119, 121, 123, 125, and 127. The first lithography layer 135 is patterned. Most of the first lithography layer 135 is removed except for the areas/locations where a jumper will be formed.

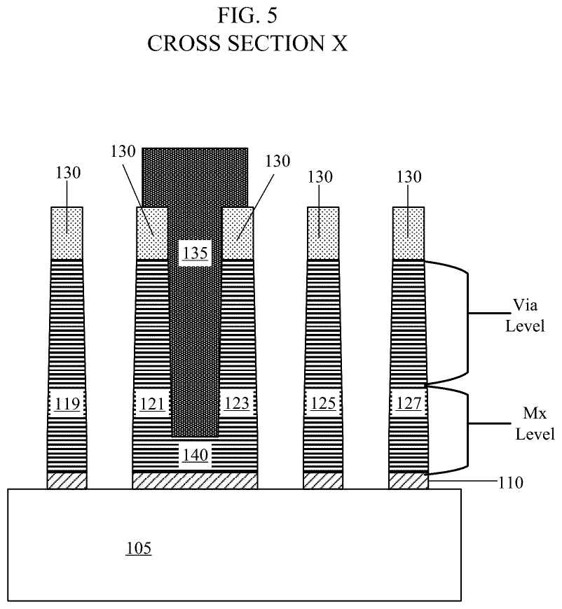

FIG. 5 illustrates the processing stage after etching of the base layer 117 and formation of the jumper 140. The first lithography layer 135 protects the location where the jumper 140 will be formed during the etching process of the base layer 117. The base layer 117 is etched, thus separating each of the plurality of metal lines 112, 121, 123, 125, and 127 from each other. A portion of the base layer 117 was protected by the first lithography layer 135. Jumper 140 or a based connector, is formed from the portion of the base layer 117 protected by the first lithography layer 135, thus the jumper 140 is formed between at least two adjacent metal lines 121 and 123. Jumper 140 is located at the base of the metal lines 121, 123, meaning that the metal lines 121, 123 extend higher than the jumper 140. Thus, jumper 140 is located on the first layer 110.

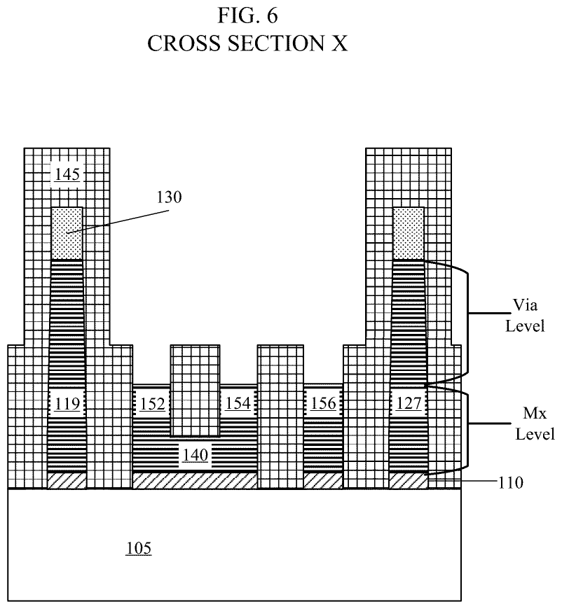

FIG. 6 illustrates the processing stage after removal of the first lithography layer 135, formation of a second lithography layer 145, and patterning/etching of the plurality of metal lines 119, 121, 123, 125, and 127. The first lithography layer 135 is removed. A second lithography layer 145 is formed around the plurality of metal lines 119, 121, 123, 125, 127. The second lithography layer 145 and some of the plurality of metal lines 121, 123, and 125 are etched to remove the via level of the metal lines 121, 123, 125, thus leaving Mx metal lines 152, 154, 156. Jumper 140 does not need to be connected to each of the Mx metal lines 152, 154, 156. Jumper 140 is connected to adjacent Mx metal lines 152 and 154, but the jumper 140 is not connected to Mx metal line 156. Metal lines 119 and 127 still have a via level section (i.e., the integral connecting via), such that the via level section of metal lines 119, 127 extends higher than the height of Mx metal lines 152, 154, 156. Jumper 140 is located around/at the base of the Mx metal lines 152, 154, such that the height of the Mx metal lines 152, 154 is greater than the height of the jumper 140.

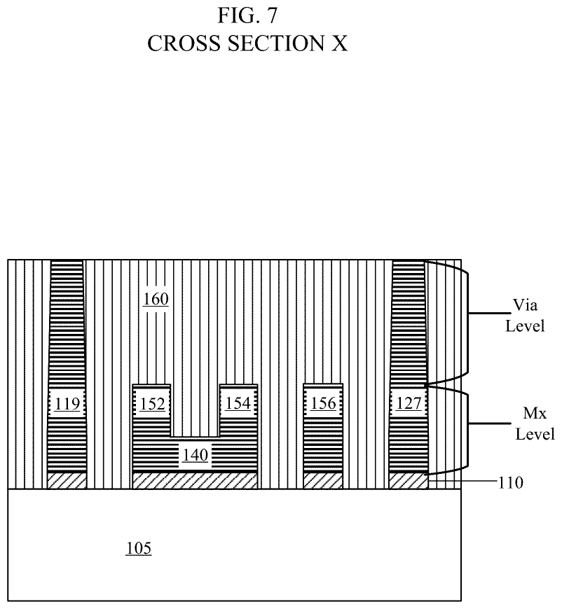

FIG. 7 illustrates the processing stage after removal of the second lithography layer 145 and the hardmask 130, formation of an interlayer dielectric layer 160. The second lithography layer 145 and the remaining portions of hardmask 130 are removed. The removal of these layers exposes the plurality of metal lines 119, 127, the Mx metal lines 152, 154, 156, and jumper 140. An interlayer dielectric layer 160 is formed around and encloses these layers. Interlayer dielectric layer 160 is planarized, for example, by chemical mechanical planarization (CMP) to remove excess interlayer dielectric layer 160 material and to expose a top surface of the via level of each of the plurality of metal lines 119, 127. The top surface of Mx metal lines 152, 154, 156 remains covered by the interlayer dielectric layer 160. This means that the Mx metal lines 152, 154, 156 and the jumper 140 are buried within the interlayer dielectric layer 160.

FIG. 7 illustrates the processing stage after formation of a second interlayer dielectric layer 165 and formation of Mx+1 metal lines 170. A second interlayer dielectric layer 165 is formed on top of the interlayer dielectric layer 160 and on top of the via level of the plurality of metal lines 119, 127. The second interlayer dielectric layer 165 can be comprised of the same material as interlayer dielectric layer 160 or it can be comprised of a different material. Trenches (not shown) are formed in the second interlayer dielectric layer 165. The trenches are filled with a conductive metal to form Mx+1 metal lines 170. The Mx+1 metal lines 170 are in direct contact with the top surface of the via level of the plurality of metal lines 119, 127. The interlayer dielectric layer 160 is located between the Mx+1 metal lines 170 and the Mx metal lines 152, 154, 156 and the jumper 140. The top surface of the Mx metal lines 152, 154, 156 is closer to a bottom surface the Mx+1 metal lines 170 than a top surface of the jumper 140. If the interconnect 106 is located on the frontside of the underlying device 105, and the device is flipped over than the directions mention here in this application will be flipped.

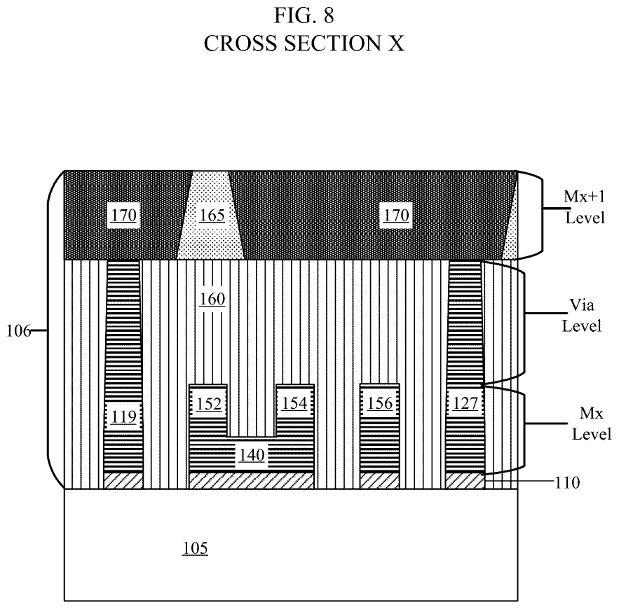

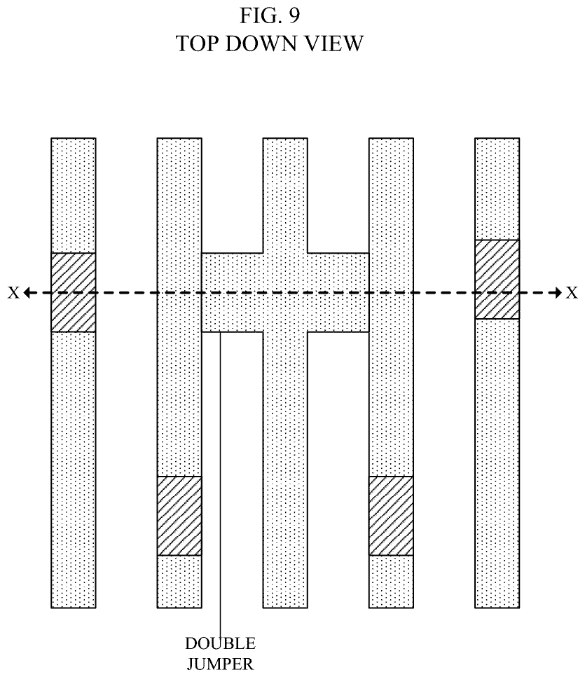

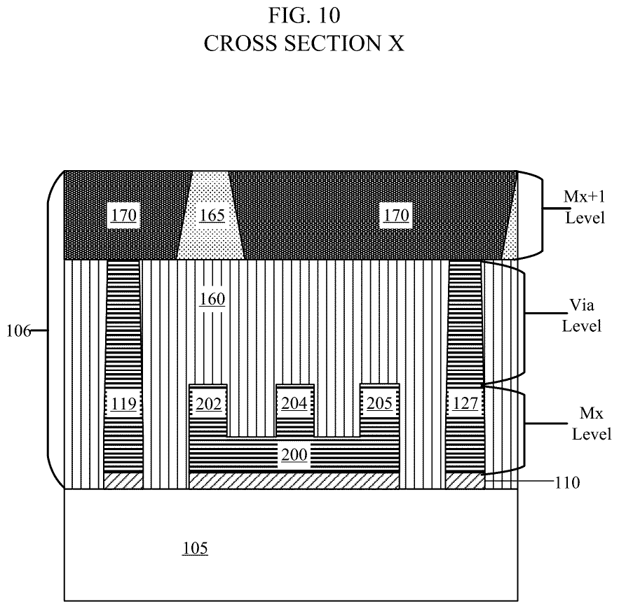

FIGS. 9 and 10 illustrate the processing stage of an interconnect utilizing a double jumper 200 after formation of a second interlayer dielectric layer 165 and formation of Mx+1 metal lines 170. FIGS. 9 and 10 utilize similar components with similar reference numbers as illustrated in FIG. 8. Explanation of these components can be found above. FIGS. 1 and 8 illustrate the use of a single jumper 140, i.e., the single jumper 140 connects two adjacent Mx metal lines 152, 154. FIGS. 9 and 10 illustrate a double jumper 200, i.e., the double jumper 200 connects multiple adjacent Mx metal lines 202, 204, 205. FIGS. 9 and 10 illustrate that the double jumper 200 forms a connection with three Mx metal lines 202, 204, 205, where Mx metal line 204 is adjacent to Mx metal line 202 and Mx metal line 205. This disclosure is not meant to be seen as limiting the number of Mx metal lines 202, 204, 205 that the jumper 200 can be connected to. The design of the interconnect will determined which Mx metal lines 152, 154, 202, 204, 205, or other lines that the jumper 140, 200 will connect to.

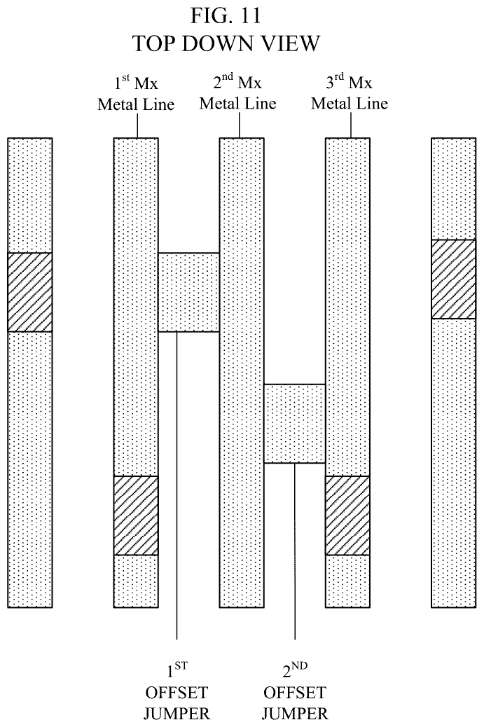

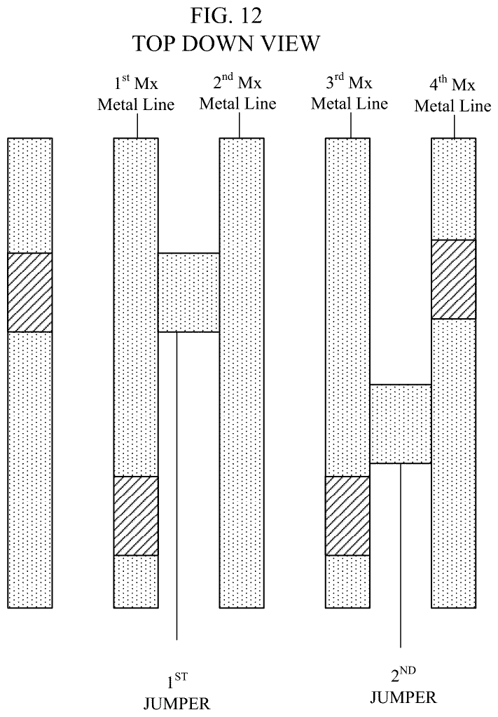

FIG. 11 illustrates a top-down view of an interconnect having two offset jumpers and FIG. 12 illustrates a top-down view of an interconnect having a plurality of jumpers. FIG. 11 illustrates a plurality of jumpers (140, 200) connecting three adjacent metal lines. FIGS. 9 and 10 illustrate a double jumper 200 where the jumper 200 extends across three Mx metal lines in a common axis. FIG. 11 illustrates the use of multiple jumpers 140 that are offset from each other to connect three Mx metal lines, i.e., the jumpers 140 are separate from each other and not located on a common axis. FIG. 12 illustrates the use of a plurality of jumpers 140 connected a plurality of different Mx metal lines. FIG. 12 illustrates that plurality of single jumper 140 used in the interconnect but each of the plurality of jumper connects two different adjacent Mx metal lines. The interconnect is not limited to the formation of a single type of jumper, but the design of the interconnect can utilize any type of buried jumpers. For example, the interconnect can include buried double jumpers, buried offset jumpers, buried single jumpers, or any combination thereof.

A microelectronic structure including an underlying device 105. An interconnect 106 located on the underlying device 105. Interconnect 106 includes a first Mx metal line 152 and a second Mx metal line 154. The first Mx metal line 152 is located adjacent to the second Mx metal line 154. A jumper 140 connects the first Mx metal line 152 to the second Mx metal line 154 and the first Mx metal line 152 extends higher than the jumper 140.

The jumper 140 is located at the base of the first Mx metal line 152 and at the base of the second Mx metal line 154.

A first layer 110 located between the underlying device 105 and the first Mx metal line 152, and the first layer 110 is located between the underlying device 105 and the second Mx metal line 154. The first layer 110 is comprised of TiN or TaN. The jumper 140 is located on the first layer 110.

An interlayer dielectric layer 160 located above and around the first Mx metal line 152, the second Mx metal line 154, and the jumper 140. The interconnect 106 further includes a Mx+1 metal line 170 located on top of the interlayer dielectric layer 165. The first Mx metal line 152, the second Mx metal line 154, and the jumper 140 are located at a different height than the Mx+1 metal line 170. The interlayer dielectric layer 160 is located between the Mx+1 metal line 170 and the first Mx metal line 152, the second Mx metal line 154, and the jumper 140.

A microelectronic structure including an underlying device 105 and an interconnect 106 located on the underlying device 105. The interconnect 106 includes a plurality of Mx metal lines 119, 127, 152, 154, 156, where at least one Mx metal lines 119, 127 of the plurality of Mx Metal lines 119, 127, 152, 154, 156 includes an integral connecting via (i.e., the via level illustrated in the Figures). At least one jumper 140 connecting at least two adjacent Mx metal lines 152, 154 of the plurality of Mx metal lines 119, 127, 152, 154, 156. The at least one Mx metal line 119, 127 with the integral connecting via (i.e., the via level illustrated in the Figures) extends higher than the at least two adjacent Mx metal lines 152, 154.

The at least one jumper 140 is located at the base of the at least two adjacent Mx metal lines 152, 154.

A first layer 110 located between the underlying device 105 and the at least two adjacent Mx metal lines 152, 154. The first layer 110 is comprised of TiN or TaN. The at least one jumper 140 is located on the first layer 110.

The interconnect 106 further includes an interlayer dielectric layer 160 located above and around the at least one jumper 140 and the at least two adjacent Mx metal lines 152, 154. The interconnect 106 further includes at least one Mx+1 metal line 170 located on top of the interlayer dielectric layer 160. The at least one jumper 140 and the at least two adjacent Mx metal lines 152, 154 are located at a different height than the at least one Mx+1 metal line 170. The interlayer dielectric layer 160 is located between the at least one Mx+1 metal line 170 and the at least one jumper 140 and the at least two adjacent Mx metal lines 152, 154. The at least one Mx+1 metal line 170 is connected to a top surface of the at least one Mx metal line 119, 127 that includes the integral connecting via (as illustrated in FIGS. 8 and 10).

A microelectronic structure including an underlying device 105 and an interconnect 106 located on the underlying device 105. The interconnect 106 includes a plurality of Mx metal lines 119, 127, 202, 204, 205 (or 152, 154, 156). At least one or more jumpers 140, 200 connecting a group Mx metal lines 202, 204, 205 (or 152, 154, 156) of the plurality of Mx metal lines 119, 127, 202, 204, 205. The group of Mx metal lines 202, 204, 205 (or 152, 154, 156) includes three adjacent Mx metal lines 202, 204, 205. Each of the Mx metal lines 202, 204, 205 (or 152, 154, 156) in the group of Mx metal lines extends higher than the at least one or more jumpers 140, 200.

The at least one or more jumpers 140, 200 is a double jumper 200. The double jumper 200 extends laterally to connect the three adjacent Mx metal lines 202, 204, 205 of the group of Mx metal lines.

At least one or more jumpers 140 is comprised of two jumpers 140 to connect the three adjacent Mx metal lines 152, 154, 156 of the group of Mx metal lines. The two jumpers 140 are offset from each other as illustrated in FIG. 11.

A method including the steps of forming an underlying device 105 and forming an interconnect 106 located on the underlying device 105. Interconnect 106 includes a first Mx metal line 152 and a second Mx metal line 154 and the first Mx metal line 152 is located adjacent to the second Mx metal line 154. A jumper 140 connects the first Mx metal line 152 to the second Mx metal line 154 and the first Mx metal line 152 extends higher than the jumper 140. The jumper 140 is located at the base of the first Mx metal line 152 and at the base of the second Mx metal line 154.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
an underlying device;
an interconnect located on the underlying device, wherein the interconnect comprises:
a first Mx metal line and a second Mx metal line, wherein the first Mx metal line is located adjacent to the second Mx metal line; and
a jumper connects the first Mx metal line to the second Mx metal line, wherein the first Mx metal line extends higher than the jumper.

2. The microelectronic structure of claim 1, wherein the jumper is located at a base of the first Mx metal line and at a base of the second Mx metal line.

3. The microelectronic structure of claim 1, further comprising:
a first layer located between the underlying device and the first Mx metal line, and the first layer is located between the underlying device and the second Mx metal line.

4. The microelectronic structure of claim 3, wherein the first layer is comprised of TiN or TaN.

5. The microelectronic structure, of claim 4 wherein the jumper is located on the first layer.

6. The microelectronic structure of claim 1, wherein the interconnect further comprises:
an interlayer dielectric layer located above and around the first Mx metal line, the second Mx metal line, and the jumper.

7. The microelectronic structure of claim 6, wherein the interconnect further comprises:
a Mx+1 metal line located on top of the interlayer dielectric layer.

8. The microelectronic structure of claim 7, wherein the first Mx metal line, the second Mx metal line, and the jumper are located at a different height than the Mx+1 metal line.

9. The microelectronic structure of claim 8, wherein the interlayer dielectric layer is located between the Mx+1 metal line and the first Mx metal line, the second Mx metal line, and the jumper.

10. A microelectronic structure comprising:
an underlying device;
an interconnect located on the underlying device, wherein the interconnect comprises:
a plurality of Mx metal lines, wherein at least one Mx metal line of the plurality of Mx Metal lines includes an integral connecting via; and
at least one jumper connecting at least two adjacent Mx metal lines of the plurality of Mx metal lines, wherein the at least one Mx metal line with the integral connecting via extends higher than the at least two adjacent Mx metal lines.

11. The microelectronic structure of claim 10, wherein the at least one jumper is located at a base of the at least two adjacent Mx metal lines.

12. The microelectronic structure of claim 10, further comprising:
a first layer located between the underlying device and the at least two adjacent Mx metal lines.

13. The microelectronic structure of claim 12, wherein the first layer is comprised of TiN or TaN.

14. The microelectronic structure of claim 13, wherein the at least one jumper is located on the first layer.

15. The microelectronic structure of claim 10, wherein the interconnect further comprises:
an interlayer dielectric layer located above and around the at least one jumper and the at least two adjacent Mx metal lines.

16. The microelectronic structure of claim 15, wherein the interconnect further comprises:
at least one Mx+1 metal line located on top of the interlayer dielectric layer.

17. The microelectronic structure of claim 16, wherein the at least one jumper and the at least two adjacent Mx metal lines are located at a different height than the at least one Mx+1 metal line.

18. The microelectronic structure of claim 17, wherein the interlayer dielectric layer is located between the at least one Mx+1 metal line and the at least one jumper and the at least two adjacent Mx metal lines.

19. The microelectronic structure of claim 18, wherein the at least one Mx+1 metal line is connected to a top surface of the at least one Mx metal line that includes the integral connecting via.

20. A microelectronic structure comprising:
an underlying device;
an interconnect located on the underlying device, wherein the interconnect comprises:
a plurality of Mx metal lines; and
at least one or more jumpers connecting a group Mx metal lines of the plurality of Mx metal lines, wherein the group of Mx metal lines includes three adjacent Mx metal lines, wherein each of the Mx metal lines in the group of Mx metal lines extends higher than the at least one or more jumpers.

21. The microelectronic structure of claim 20, wherein the at least one or more jumpers is a double jumper, wherein the double jumper extends laterally to connect the three adjacent Mx metal lines of the group of Mx metal lines.

22. The microelectronic structure of claim 20, wherein the at least one or more jumpers is comprised of two jumpers to connect the three adjacent Mx metal lines of the group of Mx metal lines.

23. The microelectronic structure of claim 22, wherein the two jumpers are offset from each other.

24. A method comprising:
forming an underlying device;
forming an interconnected located on the underlying device, wherein the interconnect comprises:
a first Mx metal line and a second Mx metal line, wherein the first Mx metal line is located adjacent to the second Mx metal line; and
a jumper connects the first Mx metal line to the second Mx metal line, wherein the first Mx metal line extends higher than the jumper.

25. The method of claim 24, wherein the jumper is located at a base of the first Mx metal line and at a base of the second Mx metal line.
